(19) United States
(12) Patent Application Publication
(10) Pub. No.: US 2007/0123021 A1
(43) Pub. Date: May 31, 2007

(54) Circuit under pad structure and bonding pad process

(76) Inventors: Hung-Der Su, Luju Township (TW); Chih-Ping Tan, Chiunglin Townshi (TW); Yu-Che Lin, Taipei City (TW); Yuh-Chyuan Wang, Taichung City (TW); Chao-Kang Ho, Jubei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/603,027

(22) Filed: Nov. 22, 2006

(30) Foreign Application Priority Data
Nov. 25, 2005 (TW) 094141580

(51) Int. Cl. H01L 21/44

(52) U.S. Cl. 438/612

(57) ABSTRACT

A circuit under pad structure comprises a bonding pad to provide a bonding region and a probing region which are not overlapped to each other, so as to reduce the pounding to the structure under the bounding pad during the test and package process. A simple process for forming the circuit under pad structure is further provided, which comprises formation of a passivation layer over the bonding pad, and etch to the passivation layer to form two openings for exposing the bonding pad so as to provide the bonding region and the probing region.

### FIELD OF THE INVENTION

The present invention is related generally to a bonding pad of a chip and, more particularly, to a circuit under pad (CUP) structure and a bonding pad process of forming the circuit under pad structure.

### BACKGROUND OF THE INVENTION

For the signal connections of an integrated circuit (IC) inside a chip and outside the package of the chip, bonding pads are necessary elements of the chip for bonding wires or growing bumps thereon. To prevent the integrated circuit of a chip from being damaged, conventionally, a bonding pad would not be arranged on the upper position of the integrated circuit. Since the position of each bonding pad is so required not to overlap on the integrated circuit, a conventional chip needs a larger area to provide enough space for the bonding pads.

The bonding pad would be stricken during a package process. For example, in the process of bonding a wire to a bonding pad, the impact to the bonding pad when throwing a melt metal ball and the pull to the bonding pad when dragging the bonding wire would easily make the bonding pad to be broken or peeled. Conventionally, the efforts are made to improve the breaking or peeling of bonding pads and to reduce the size of bonding pads, and it would not focus on the impact to the integrated circuit inside the chip during the bonding process, since the integrated circuit is not right under the bonding pads.

In the backend process of a semiconductor product, test is generally applied to the circuit inside a chip before the package process, which comprises a circuit probing (CP) to the bonding pad for electric test. The probe would cause a probe mark on the pad surface and which, during the bonding process later, would cause a poor bonding between the metal ball and the bonding pad and thereby the peeling of the metal ball from the bonding pad when dragging the bonding wire. Therefore, U.S. Pat. No. 6,251,694 to Liu proposes a method which separates the probing region from the bonding region, and after the circuit probing process, covers the bonding pad with a passivation layer and then etches the passivation layer to expose the bonding region. However, even this art decreases the probability of peeling the metal ball from the bonding pad, the additional steps of forming and etching the passivation layer make the process more complicated and difficult, and it also requires a larger bonding pad to offer the separated bonding region and probing region. Under the requirement of smaller integrated circuit and higher density of chip packaging, this art gradually becomes not suitable for semiconductor chips.

On the other hand, a technology called circuit under pad (CUP) has been proposed, which violates the rule of conventional layout for a chip and arranges the bonding pad right over the circuit inside the chip to decrease the chip area and reduce the cost. If it is employed in a chip, however, the circuit under the bonding pad would easily suffer extra damage during the following CP and package processes. Especially, after a probe mark made on the bonding pad, it is needed a much stronger bonding force for good bonding between the metal ball and the bonding pad, and this will pound the structure under the bonding pad more serious. Therefore, a conventional circuit under pad structure needs one more metal layer under the bonding pad as a buffer to bear the stress and thereby reduce the damage during the CP and bonding processes. As a result, it is hard to form a circuit under pad structure by a simple process which uses less metal layers.

### SUMMARY OF THE INVENTION

An object of the present invention is to provide a circuit under pad structure.

Another object of the present invention is to provide a bonding pad process.

In a circuit under pad structure, according to the present invention, a bonding pad over a substrate is covered by a passivation layer, the passivation layer has two openings for exposing the bonding pad to provide a bonding region and a probing region, the substrate has a circuit therein, and the circuit has a portion under at least one of the bonding region and the probing region. Since the bonding region and the probing region are not overlapped to each other, the circuit under pad structure would suffer less pounding. In an embodiment, there is no buffer layer under the bonding pad.

In a bonding pad process, according to the present invention, a bonding pad is formed over a substrate, a passivation layer is formed over the bonding pad, the passivation layer is etched to form two openings for exposing the bonding pad to provide a bonding region and a probing region. The process becomes simpler since the bonding region and the probing region are formed at the same time. In an embodiment, the positions of the bonding region and the probing region are so selected that there will be a portion of a circuit in the substrate under at least one of the bonding region and the probing. Therefore, a circuit under pad structure is so formed by a simple process.

### BRIEF DESCRIPTION OF DRAWINGS

These and other objects, features and advantages of the present invention will become apparent to those skilled in the art upon consideration of the following description of the preferred embodiments of the present invention taken in conjunction with the accompanying drawings, in which:

FIG. 1 shows a cross-sectional view of a chip in an embodiment according to the present invention;

FIGS. 2 to 5 show the cross-sectional view of the chip in each step of a process to form the structure shown in FIG. 1; and

FIG. 6 shows a cross-sectional view of a chip in another embodiment according to the present invention.

### DETAILED DESCRIPTION OF THE INVENTION

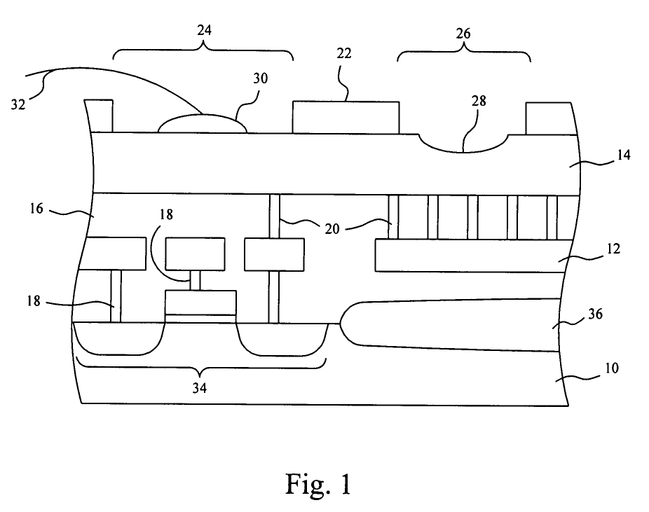

Typically, after the structure of the integrated circuit is manufactured on a substrate, a metallization is carried out for interconnect of the integrated circuit, and a bonding pad process follows thereafter. FIG. 1 shows a cross-sectional view of a chip to dramatically picture the structure of the chip after CP and wire bonding processes. On a substrate 10, there are two metal layers 12 and 14, and the former is the one for the interconnection which is manufactured by the metallization, and the later is the one for the bonding pad. A dielectric layer 16 is filled between the metal layers 12 and 14, and between the metal layer 12 and the substrate 10, for insulation. Contacts 18 and vias 20 are formed in the dielectric layer 16, and the former are for electric connections between the metal layer 12 and the circuit in the substrate 10, and the later are for electric connections between the metal layers 12 and 14. A passivation layer 22 on the metal layer 14 is pattered to define a bonding region 24 and a probing region 26, and the probing region 26 will have a probe mark thereon after it is touched by a probe in a CP process. After a bonding process, the bonding region 24 of the bonding pad 14 will have a metal ball 30 thereon, which will be further connected to a package substrate through a bonding wire 32, for example onto an inner lead of a leadframe or a bonding pad of an IC carrier.

In this embodiment, under the bonding region 24 is a circuit 34, for example an electrostatic discharge (ESD) circuit, a diode, a metal-oxide-semiconductor (MOS) device, a capacity, or any other structure of a circuit device. Under the probing region 26 is an insulator 36, for example a field oxide (FOX) or a shallow trench isolation (STI). Because the bonding region 24 does not overlap the probing region 26, the impact to the structure under the bonding pad 14 would be reduced. Especially, the top surface of the bonding region 24 will not be damaged by probe, and therefore the force of throwing the metal ball 30 when bonding the wire 32 could be much less. As a result, the yield and the reliability of the semiconductor chips can be increased. Since the structure under the bonding pad 14 will suffer less pounding during the CP and bonding processes, it is not needed to add a buffer metal layer between the bonding pad 14 and the metal layer 12. Further, because the bonding pad 14 is arranged above the circuit 34, the chip area and the cost can be reduced.

In other embodiments, it may alternatively arrange the bonding region 24 above a field oxide or a STI 36, and the circuit 34 under the probing region 26, or arrange both the bonding region 24 and the probing region 26 are above the circuit 34.

Although it is not require to add a buffer layer under the bonding pad 14 according to the present invention, in some applications, a metal layer can be still added for buffering.

In some specific applications, the circuit under pad structure of the present invention is used in a power management chip, and in this case, the area of the probing region 26 would be smaller than that of the bonding region 24, thereby further reducing the chip area.

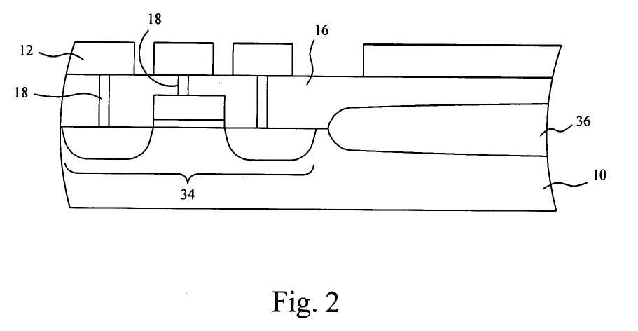

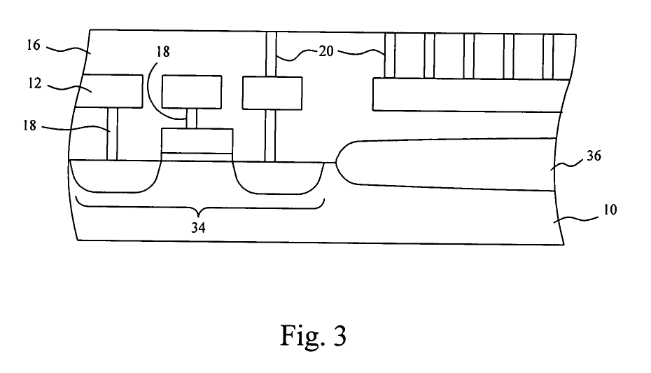

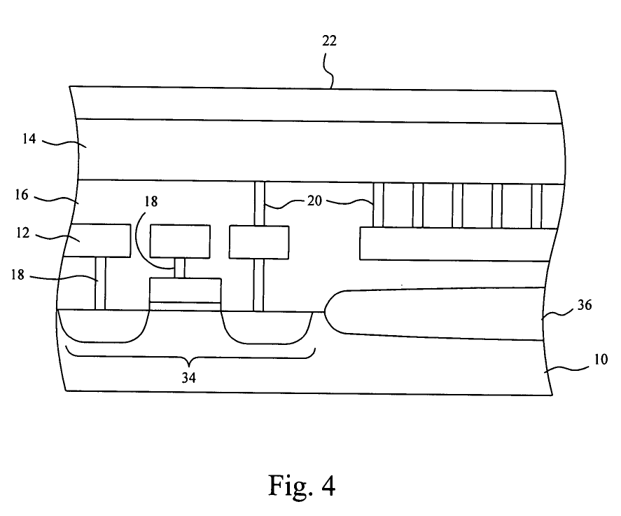

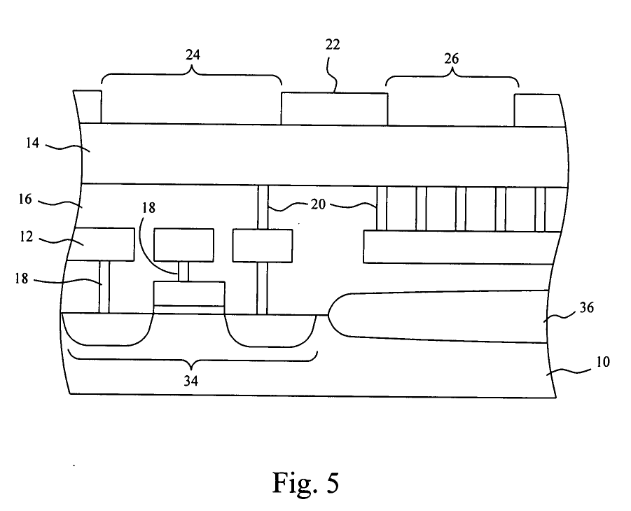

FIGS. 2 to 5 dramatically show a process of forming the structure shown in FIG. 1. FIG. 2 shows a structure before a bonding pad is formed, and as in a conventional process, it comprises the formation of the field oxide or STI 36 and the circuit 34 in the substrate 10, the deposition of the dielectric layer 16, the formation of the contacts 18, and a first metal interconnection, whereby the top surface includes a portion of the metal layer 12 and a portion of the dielectric layer 16. Then, a dielectric layer is further deposited, planarized, and etched, as shown in FIG. 3, such that the dielectric layer 16 becomes thicker and covers the metal layer 12, with the vias 20 therein for connecting to the bonding pad that will be formed in following step. In FIG. 4, a metal layer is deposited and etched to provide the bonding pad 14, and then the passivation layer 22 is deposited to cover the bonding pad 14. In FIG. 5, the passivation layer 22 is etched to form two openings to define the bonding region 24 and the probing region 26 on the bonding pad 14. Since the bonding region 24 and the probing region 26 are formed at the same time by etching the passivation layer 22, this process is simple. If this process is employed to form a circuit under pad structure, as shown in FIGS. 2 to 5, it does not require to form an extra metal layer between the metal layers 12 and 14 for buffer layer, thereby simplifying the process.

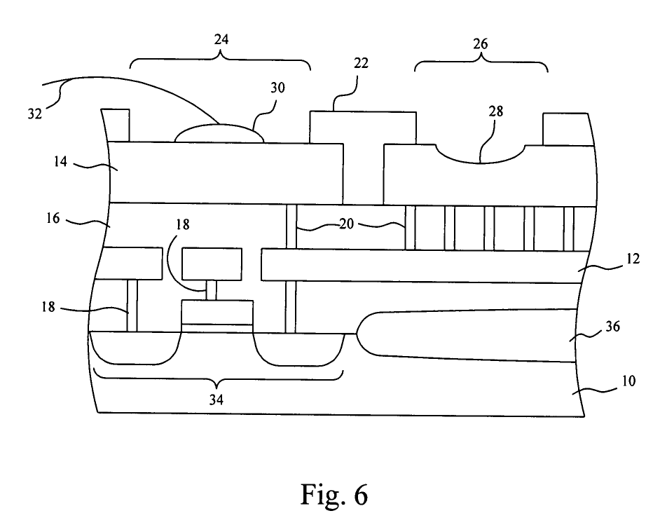

FIG. 6 shows a cross-sectional view of a chip in another embodiment according to the present invention, in which the bonding pad 14 is separated by the passivation layer 22 to be two portions for providing the bonding region 24 and the probing region 26 respectively. The metal layer 12 extends from under the probing region 26 to under the bonding region 24, such that the bonding region 24 and the probing region 26 may electrically connect to each other through the underlying metal layer 12.

In the embodiments for illustration, the substrate 10 refers to a semiconductor material which can be used to manufacture integrated circuit thereon, for example a silicon substrate, a semiconductor material formed on an insulator, or any other substrate which has been manufactured a circuit therein.

In the above embodiments, only a metal layer 12 is shown for the one to manufacture the interconnection. In a chip which includes more complicated integrate circuit, the interconnection may use a multilayer metal structure.

Because the bonding region 24 and the probing region 26 on the bonding pad 14 do not overlap each other, they do not have to be close to each other. For example, the probing regions of some bonding pads may be arranged far away from their respective bonding regions, or the probing regions and the bonding regions of some bonding pads are grouped together, respectively, at different positions on a chip.

The inventive bonding pad and the conventional bonding pad may be pictured by the following table:

| | | | CUP |
|---|---|---|---|
| | Damage | Package Window | Feasibility |
| Conventional | CP + Bonding | Small | Low |
| Bonding pad | | (depending on CP damage) | |
| Inventive | Bonding | Large | High |
| Bonding Pad | | | |

While the present invention has been described in conjunction with preferred embodiments thereof, it is evident that many alternatives, modifications and variations will be apparent to those skilled in the art. Accordingly, it is intended to embrace all such alternatives, modifications and variations that fall within the spirit and scope thereof as set forth in the appended claims.

What is claimed is:

1. A circuit under pad structure comprising:
a bonding pad over a substrate having a circuit therein; and
a passivation layer over the bonding pad, the passivation layer having two openings for exposing the bonding pad to provide a bonding region and a probing region;
wherein the circuit has a portion under the bonding region or the probing region.

2. The circuit under pad structure of claim 1, wherein the portion of the circuit is under the bonding region.

3. The circuit under pad structure of claim 2, further comprising a field oxide having a portion under the probing region.

4. The circuit under pad structure of claim 2, further comprising a shallow trench isolation having a portion under the probing region.

5. The circuit under pad structure of claim 1, wherein the portion of the circuit is under the probing region.

6. The circuit under pad structure of claim 5, further comprising a field oxide having a portion under the bonding region.

7. The circuit under pad structure of claim 5, further comprising a shallow trench isolation having a portion under the bonding region.

8. The circuit under pad structure of claim 1, wherein the portion of the circuit is under both the bonding region and the probing region.

9. The circuit under pad structure of claim 1, wherein the bonding region and the probing region are separated by the passivation layer and electrically connected to each other through a metal layer which has a portion under the bonding pad.

10. A bonding pad process comprising the steps of:
forming a bonding pad over a substrate having a circuit therein;
forming a passivation layer over the bonding pad; and
etching the passivation layer for forming two openings to expose the bonding pad so as to provide a bonding region and a probing region.

11. The bonding pad process of claim 10, wherein the bonding region and the probing region are so selected for their positions that the circuit has a portion under the bonding region or the probing region.

12. The bonding pad process of claim 10, wherein the bonding region and the probing region are so selected for their positions that the circuit has a portion under the bonding region and a field oxide has a portion under the probing region, or the circuit has a portion under the probing region and a field oxide has a portion under the bonding region.

13. The bonding pad process of claim 10, wherein the bonding region and the probing region are so selected for their positions that the circuit has a portion under the bonding region and a shallow trench isolation has a portion under the probing region, or the circuit has a portion under the probing region and a shallow trench isolation has a portion under the bonding region.

14. The bonding pad process of claim 10, wherein the bonding region and the probing region are separated by the passivation layer and electrically connected to each other through a metal layer which has a portion under the bonding pad.
